(19) United States
(12) Patent Application Publication
(10) Pub. No.: US 2012/0120564 A1
(43) Pub. Date: May 17, 2012

(54) ELECTRONIC APPARATUS

(75) Inventors: Chih Kuo Lu, Taipei (TW); Sheng Wen Hu, Taipei (TW); Dong Sen Chen, Taipei (TW)

(73) Assignee: INVENTEC CORPORATION, Taipei (TW)

(21) Appl. No.: 13/014,380

(22) Filed: Jan. 26, 2011

(30) Foreign Application Priority Data
Nov. 17, 2010 (TW) 099139608

(51) Int. Cl. H05K 7/00

(52) U.S. Cl. 361/679.01

(57) ABSTRACT

An electronic device includes a shell body, an input component, a backlight board, and a transparent cover. The shell body has a top surface and a bearing tank located on the top surface. The input component is disposed in the bearing tank, and the backlight board is superposed on the input component and is located in the bearing tank. The bearing tank exposes the backlight board. In addition, the transparent cover is superposed on the backlight board, so as to achieve the waterproof effect.

### CROSS-REFERENCE TO RELATED APPLICATIONS

This non-provisional application claims priority under 35 U.S.C. §119(a) on Patent Application No(s). 099139608 filed in Taiwan, R.O.C. on Nov. 17, 2010, the entire contents of which are hereby incorporated by reference.

### BACKGROUND OF THE INVENTION

1. Field of Invention

The present invention relates to an electronic apparatus, in particular, to an electronic apparatus applicable to a notebook computer.

2. Related Art

In recent years, with the rapid change of technology and information, notebook computers have more powerful functions, and a user may perform word processing or enjoy multimedia entertainment through the computer. However, a general notebook computer in the market usually has a keyboard which is the most basic input apparatus of the notebook computer. Generally, the conventional keyboard structure includes a bottom board, a membrane circuit board, an elastic component, a plurality of brackets and a plurality of keycaps. Moreover, the keyboard is composed by the bottom board, the membrane circuit board, the elastic component, the brackets and the keycaps stacked in sequence. Therefore, the thickness of the keyboard is the thickness of the stack of the above components, and the thickness of the general keyboard varies from 4-6 millimeters. Moreover, all the present electronic products develop towards the trend of light, thin, short and small, and therefore, it is an objective of researchers to reduce the keyboard thickness. However, restricted by the structure, the thickness of the conventional keyboard gradually reaches a limit.

In addition, the conventional keyboard is generally installed on the case of the notebook computer, so a gap often exists between the keyboard and the case. When the user accidentally knocks over liquid (water or coffee) on the keyboard, the liquid may flow into the computer along the gap between the keyboard and the case, thus causing damage to the internal electronic components. Therefore, the waterproof function of the keyboard is also a concern the researchers. Currently, the waterproof specification of the keyboard is generally that the liquid does not flow into the interior of the computer system in a certain period of time. In other words, no really waterproof keyboard exists in the market, and when the user accidentally knocks over the liquid on the keyboard, the computer will be inevitably damaged to some extent.

### SUMMARY OF THE INVENTION

Accordingly, the present invention is an electronic apparatus, which solves the problems in the prior art that it is difficult to reduce the keyboard thickness, and that the waterproof function of the keyboard is poor.

The present invention provides an electronic apparatus, which comprises a shell body, an input component, a backlight board, and a transparent cover. The shell body has a top surface and a bearing tank located on the top surface. The input component is disposed in the bearing tank, and the backlight board is superposed on the input component and is located in the bearing tank. The bearing tank exposes the backlight board. In addition, the transparent cover is superposed on the backlight board.

In the electronic apparatus according to an embodiment of the present invention, the conventional keyboard is replaced by a touch input apparatus, and therefore the thickness is thinner than that of the conventional keyboard so as to meet the trend of being thinner. According to the electronic apparatus of the present invention, the input component and the backlight board are covered by the transparent cover and the shell body, which meets the waterproof requirement of the electronic products.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 is a schematic structural view of an electronic apparatus according to an embodiment of the present invention;

FIG. 2A is a combined structural view of an electronic apparatus according to an embodiment of the present invention;

FIG. 2B is a sectional structural view along a section line 2B-2B of the electronic apparatus of FIG. 2A;

FIG. 3 is a schematic structural view of a backlight board according to an embodiment of the present invention;

FIG. 4A is a schematic structural view of a transparent cover according to an embodiment of the present invention;

FIG. 4B is a sectional structural view of a transparent cover according to an embodiment of the present invention; and

FIG. 5 is a schematic structural view of an electronic apparatus according to another embodiment of the present invention.

### DETAILED DESCRIPTION OF THE INVENTION

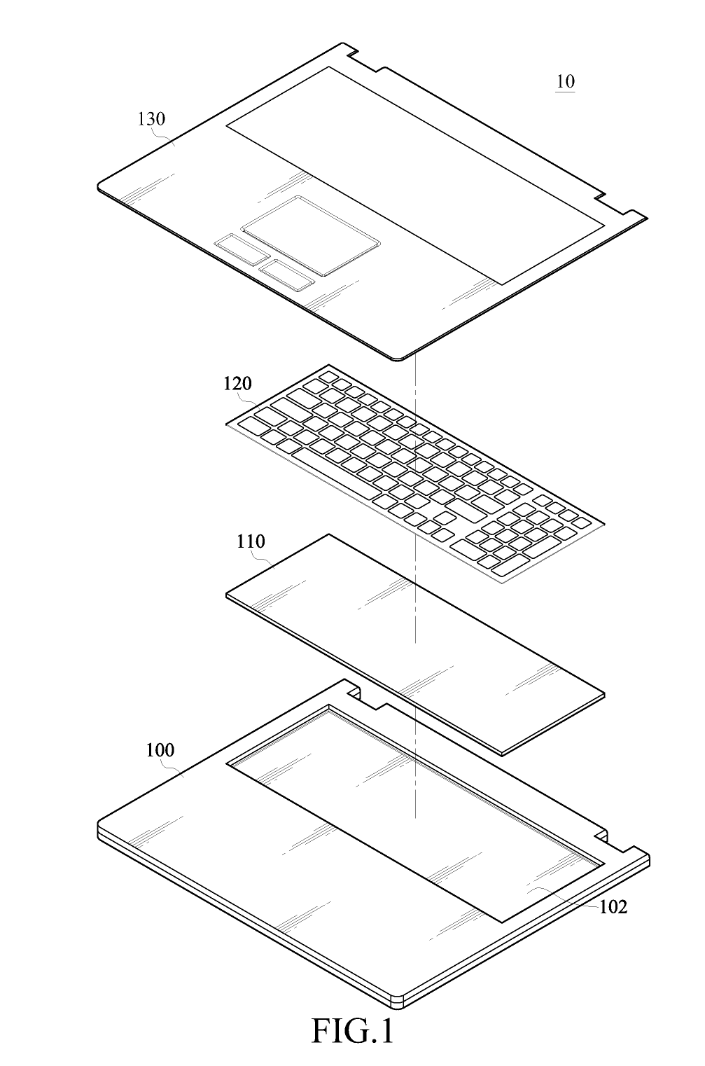

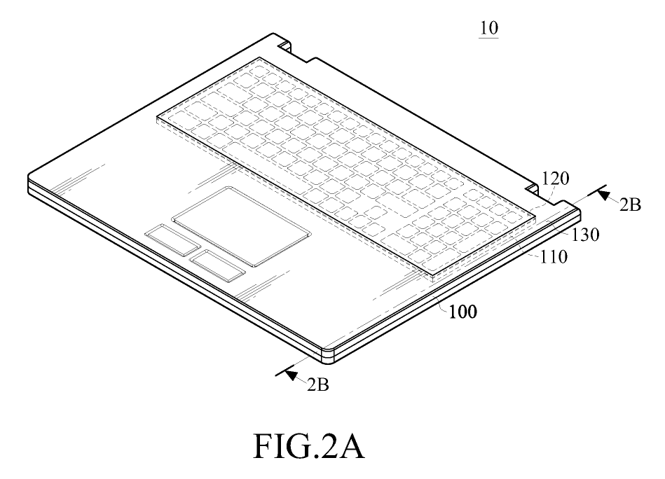

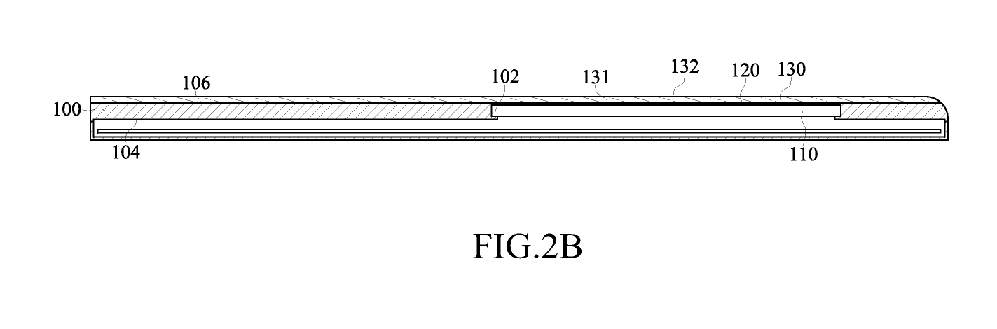

Referring to FIGS. 1, 2A and 2B, FIG. 1 is a schematic structural view of an electronic apparatus according to an embodiment of the present invention, FIG. 2A is a combined structural view of the electronic apparatus of FIG. 1, and FIG. 2B is a sectional structural view along a section line 2B-2B of the electronic apparatus of FIG. 2A.

An electronic apparatus 10 according to an embodiment of the present invention is applicable to a common notebook computer, and can replace the keyboard of a conventional notebook computer. The electronic apparatus 10 comprises a shell body 100, an input component 110, a backlight board 120, and a transparent cover 130. The shell body 100 has a top surface 106 and a bottom surface 104 which are opposite to each other. The shell body also has a bearing tank 102, and the bearing tank 102 is formed on the top surface 106.

In addition, the input component 110 is disposed in the bearing tank 102, and may be a touch button such as a capacitive touch sense button, but is not thus limited; for example the input component 110 may also be other touch input apparatuses.

In this embodiment, the backlight board 120 is superposed on the input component 110, located in the bearing tank 102, and exposed out of the shell body 100 through the bearing tank 102. The backlight board 120 may indicate the location of virtual buttons of the input component 110, so as to facilitate the identification of the user. When the input component 110 and the backlight board 120 are located in the bearing tank 102, the input component 110 and the backlight board 120 may further be surrounded by the shell body 100. In addition, the transparent cover 130 further has a surface 132 and a joint surface 131 which are opposite to each other, and the transparent cover 130 is superposed on the backlight board 120 through the joint surface 131. Moreover, the transparent cover 130 may further be superposed on the top surface 106 of the shell body 100 through the joint surface 131 at the same time, and entirely covers the bearing tank 102. That is, the input component 110 and the backlight board 120 are enclosed in the bearing tank 102 by the transparent cover 130 and the shell body 100. Since the bearing tank 102 is entirely enclosed by the transparent cover 130, the electronic apparatus 10 has the waterproof effect, thus avoiding damage to the input component 110 or the backlight board 120 due to the invasion of liquid (water or coffee), and even preventing the liquid from flowing into the interior of the computer system.

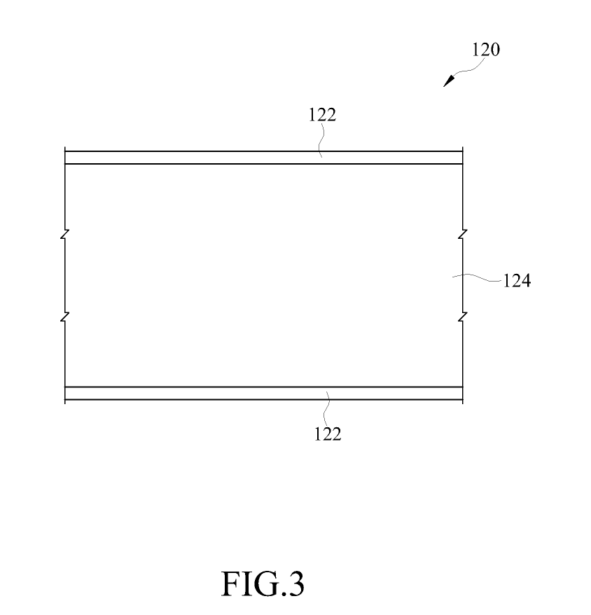

FIG. 3 is a schematic structural view of a backlight board according to an embodiment of the present invention. Referring to FIG. 3, the backlight board 120 in this embodiment may also be an Electro Luminescent (EL) board. The EL effect is a phenomenon that electrical energy is converted into light energy, and no heat is generated in the operation process thereof, so the EL is commonly called “luminescence”. Two electrodes 122 are disposed on two opposite ends of the backlight board 120 in this embodiment, and a luminescent material 124 is filled between the two electrodes 122. The luminescent material 124 may be sulfide, such as zinc sulfide, calcium sulfide or strontium sulfide. In addition, the luminescent material 124 between the two electrodes 122 may also add fluorescent dye, so as to make the luminescent effect more variable. The backlight board 120 provides the electronic apparatus 10 with the backlight effect, which facilitates the use of the user in a dark environment.

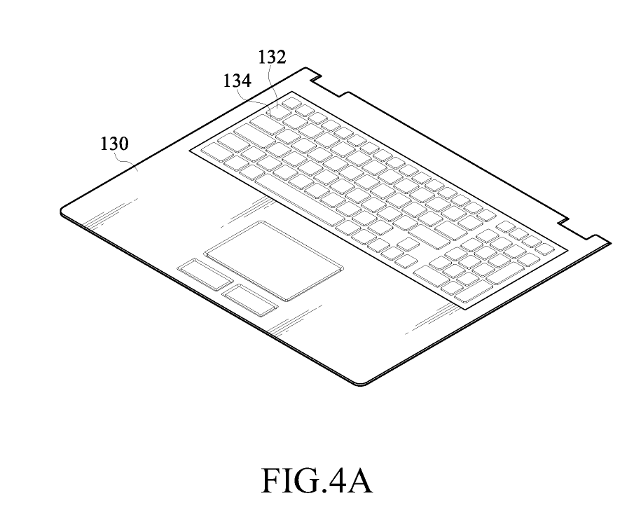

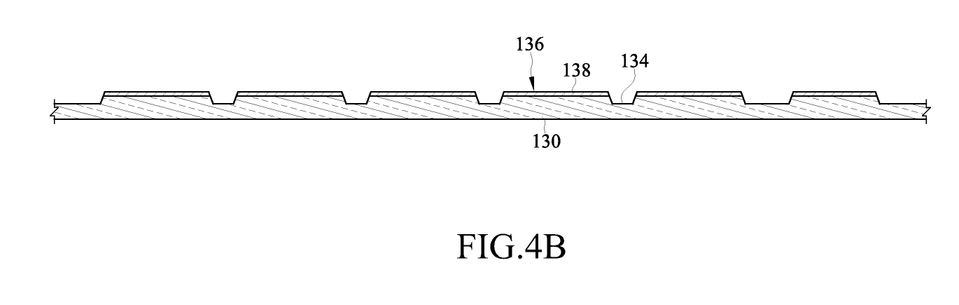

Referring to FIG. 4A and FIG. 4B in combination with FIG. 2B, FIG. 4A is a schematic structural view of a transparent cover according to an embodiment of the present invention, and FIG. 4B is a sectional structural view of a transparent cover according to an embodiment of the present invention.

The material of the transparent cover 130 in this embodiment may further be tempered glass, which has the features of high strength, high rigidity, high hardness, high impact-resistance and high abrasion-resistance. Therefore, the transparent cover 130 using the tempered glass as the material prevents the input component 110 and the backlight board 120 in the bearing tank 102 from damage caused by the collision of an external force. In addition, the surface 132 of the transparent cover 130 is an exterior surface of the electronic apparatus 10. The surface 132 of the transparent cover 130 further has a plurality of crossing grooves 134. Since the plurality of crossing grooves 134 are formed on the surface 132, a plurality of bumps 136 is correspondingly formed on the surface 132, and the positions of the bumps 136 may correspond to the button positions (touch buttons) of the input component 110. The bumps 136 are used to simulate keycaps of a common mechanical keyboard, so that the user has better touch feeling. In addition, a layer of elastic material 138 may also be coated on the bumps 136, such as rubber paint, which, however, is not limited herein. The elastic material 138 coated on the bumps 136 may provide the user with special touch effect. In addition, a printed layer may further be covered on the bumps 136, which is corresponding to input symbols on the keycaps of the conventional keyboard. The user may correspondingly trigger the input component 110 (the touch buttons) under the backlight board 120 by touching the bumps 136, so that the input component 110 correspondingly generates signals indicated by the printed input symbols on the bumps 136.

Since the user can trigger the input component 110 by touching the bumps 136, the electronic apparatus 10 eliminates the noise generated when a user uses the conventional keyboard, and eases the burden of the hands when the user operates the computer for a long time.

According to the electronic apparatus 10 in this embodiment, an input apparatus is formed by stacking the input component 110, the backlight board 120 and the transparent cover 130. Compared with the thickness of the conventional keyboard, the thickness of the input apparatus formed by stacking the input component 110, the backlight board 120 and the transparent cover 130 is only 1.95 millimeters, so as to meet the trend of being thinner of the electronic products.

In addition, since the transparent cover 130 is closely connected to the shell body 100, so as to entirely cover the bearing tank 102, a good waterproof effect is achieved for the input component 110 and the backlight board 120. Since the electronic apparatus 10 in this embodiment uses the touch input instead of the conventional pressing keyboard, the problem that the conventional keyboard is easy to gather dust and difficult to clean is avoided.

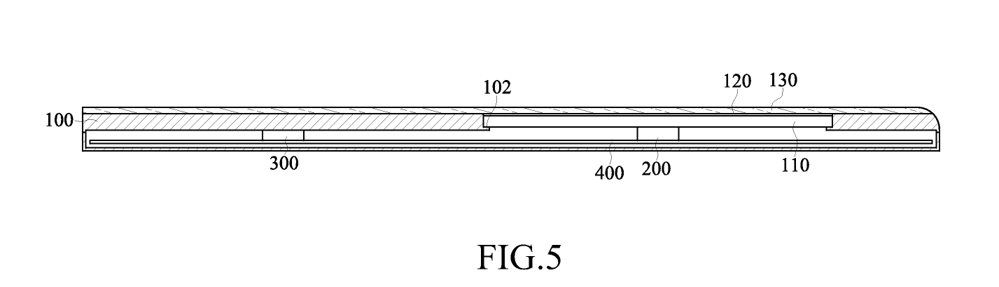

FIG. 5 is a schematic structural view of an electronic apparatus according to another embodiment of the present invention. Referring to FIG. 5, the electronic apparatus 10 in this embodiment may further comprise a control unit 200 and a vibration component 300. The control unit 200 may be disposed on a mainboard 400, and the vibration component 300 is electrically connected to the control unit 200. The input component 110, the control unit 200 and the vibration component 300 are connected to the shell body 100. When the user touches the bumps 136, the input component 110 (the touch buttons) generates a signal through induction, the control unit 200 receives the signal and converts the signal into an instruction, and the vibration component 300 vibrates the shell body 100. That is to say, when the user presses the bumps 136, the vibration effect is felt, so as to improve the touch feeling in use.

The electronic apparatus according to an embodiment of the present invention replaces the conventional keyboard with a touch input apparatus, and therefore the thickness of the electronic apparatus is thinner than that of the conventional keyboard, so as to meet the trend of being thinner of the products. In addition, in the electronic apparatus according to the embodiment, the input component and the backlight board are covered by the transparent cover and the shell body, which meets the waterproof requirement of the electronic products.

What is claimed is:

1. An electronic apparatus, comprising:
a shell body, having a top surface and a bearing tank, wherein the bearing tank is located on the top surface;
an input component, disposed in the bearing tank;
a backlight board, superposed on the input component and located in the bearing tank, wherein the bearing tank exposes the backlight board; and
a transparent cover, superposed on the backlight board.

2. The electronic apparatus according to claim 1, wherein the shell body surrounds the input component and the backlight board, the transparent cover is superposed on the backlight board and the top surface, and the transparent cover encloses the bearing tank.

3. The electronic apparatus according to claim 1, wherein the backlight board is an Electro Luminescent (EL) board, two electrodes are disposed on two opposite ends of the backlight board, and a luminescent material is filled between the two electrodes.

4. The electronic apparatus according to claim 1, wherein the transparent cover has a surface and a joint surface opposite to each other, the transparent cover is superposed on the backlight board through the joint surface, and the surface has a plurality of grooves, so that a plurality of bumps is formed on the surface.

5. The electronic apparatus according to claim 4, wherein an elastic material is coated on the bumps.

6. The electronic apparatus according to claim 1, wherein a material of the transparent cover is tempered glass.

7. The electronic apparatus according to claim 1, wherein the input component is a touch button.

8. The electronic apparatus according to claim 1, further comprising a control unit and a vibration component, wherein the control unit is electrically connected to the input component, the vibration component is connected to the shell body, and the input component transmits a signal to the control unit, so that the control unit enables the vibration component to vibrate the shell body.
